(19) United States
(12) Patent Application Publication
(10) Pub. No.: US 2021/0288135 A1
(43) Pub. Date: Sep. 16, 2021

(54) DISPLAY APPARATUS

(71) Applicant: Samsung Display Co., LTD., Yongin-si (KR)

(72) Inventors: Wonse LEE, Seoul (KR); Yu-Jin JEON, Hwaseong-si (KR)

(73) Assignee: Samsung Display Co., LTD., Yongin-si (KR)

(21) Appl. No.: 17/162,244

(22) Filed: Jan. 29, 2021

(30) Foreign Application Priority Data
Mar. 12, 2020 (KR) 10-2020-0030769

(51) Int. Cl. H01L 27/32

(52) U.S. Cl. CPC H01L 27/3279; H01L 27/3248; G09G 3/3266; G09G 2310/08; G09G 2310/0286

(57) ABSTRACT

A display apparatus includes a display, a driver including a plurality of shift registers arranged along a first direction, the driver providing a driving signal to the display, and a first signal wiring disposed on the driver, extending along the first direction, and transmitting a first driving signal to the plurality of shift resisters. Each of the plurality of shift registers includes at least one driver transistor. The first signal wiring is electrically connected to a source electrode of a first driver transistor and overlaps the first driver transistor.

### CROSS-REFERENCE TO RELATED APPLICATION(S)

This application claims priority to and benefits of Korean Patent Application No. 10-2020-0030769 under 35 U.S.C. § 119, filed on Mar. 12, 2020 in the Korean Intellectual Property Office, the entire contents of which are incorporated herein by reference.

### BACKGROUND

### 1. Technical Field

Example embodiments are directed to a display apparatus. Example embodiments are directed to a display apparatus having a reduced non-display area.

### 2. Description of the Related Art

Until recently, conventional cathode ray tubes (CRTs) have been widely used in display apparatuses with many advantages in terms of performance and price. However, recently, a display apparatus having advantages such as miniaturization or portability that overcome the shortcomings of CRTs and having advantages such as miniaturization, weight reduction, and low power consumption has attracted attention. For example, plasma displays, liquid crystal displays, organic light emitting displays, and the like are attracting attention.

Attempts have been made to reduce the bezel area of the display apparatus. For example, a bezel-less display apparatus, a display apparatus including a notch, and the like have been developed. Wirings existing in the bezel area may be rearranged to reduce the bezel area.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display apparatus having a reduced non-display area.

According to an embodiment, a display apparatus may include a display; a driver including a plurality of shift registers arranged along a first direction, the driver providing a driving signal to the display; and a first signal wiring disposed on the driver, extending along the first direction, and transmitting a first driving signal to the plurality of shift registers, wherein each of the plurality of shift registers may include at least one driver transistor, and the first signal wiring may be electrically connected to a source electrode of a first driver transistor and overlaps the first driver transistor.

In an embodiment, the first signal wiring may transmit first driving signal of a constant voltage.

In an embodiment, the first signal wiring may overlap the source electrode of the first driver transistor.

In an embodiment, the first signal wiring may overlap the source electrode and a gate electrode of the first driver transistor.

In an embodiment, the first signal wiring may overlap the source electrode, a drain electrode, and a gate electrode of the first driver transistor.

In an embodiment, the first signal wiring may overlap two or more driver transistors.

In an embodiment, the display apparatus may further include a second driver transistor; and a second signal wiring extending along the first direction and transmitting a second driving signal to a first shift register of the plurality of shift registers. The second signal wiring may overlap the second driver transistor.

In an embodiment, the second signal wiring may transmit the second driving signal as a start signal.

In an embodiment, the first signal wiring and the second signal wiring may be disposed on a same layer.

In an embodiment, the first signal wiring and the second signal wiring may be spaced apart from each other in a second direction perpendicular to the first direction.

In an embodiment, the second signal wiring may overlap a source electrode, a drain electrode, or a gate electrode of the second driver transistor.

In an embodiment, the second signal wiring may overlap a source electrode and a gate electrode of the second driver transistor.

In an embodiment, the second signal wiring may overlap a drain electrode and a gate electrode of the second driver transistor.

In an embodiment, the second signal wiring may overlap a source electrode, a drain electrode, and a gate electrode of the second driver transistor.

In an embodiment, the second signal wiring may overlap two or more driver transistors.

In an embodiment, the display apparatus may further include a clock signal wiring providing a clock signal to a second driver transistor and extending along the first direction.

In an embodiment, the clock signal wiring and the first signal wiring may be disposed on a same layer, and the clock signal wiring may not overlap the first driver transistor and second driver transistor.

In an embodiment, the clock signal wiring may be electrically connected to a source electrode of the second driver transistor.

In an embodiment, the clock signal wiring and a source electrode of the first driver transistor may be disposed on a same layer, and the clock signal wiring may not overlap the first driver transistor and the second driver transistor.

In an embodiment, the clock signal wiring may be electrically connected to the second driver transistor by a bridge electrode.

In an embodiment, the bridge electrode and a gate electrode of the first driver transistor may be disposed on a same layer.

In an embodiment, the display may include a light emitting element; a pixel driving transistor including a gate electrode, a source electrode, and a drain electrode; and a connection electrode electrically connecting the light emitting element and the drain electrode of the pixel driving transistor. The first signal wiring and the connection electrode may be disposed on a same layer.

Accordingly, a non-display area (for example, dead space) of the display apparatus may be reduced. Also, as a length of wirings decreases, a resistance may decrease.

It is to be understood that both the foregoing general description and the following detailed description are examples and explanatory and are intended to provide further explanation of the disclosure as claimed.

### BRIEF DESCRIPTION OF THE DRAWINGS

Aspects of example embodiments will be more clearly understood from the following detailed description taken in conjunction with the accompanying drawings in which:

FIG. 1 is a plan view illustrating a display apparatus according to an embodiment.

FIG. 2 is a block diagram illustrating an external device electrically connected to the display apparatus of FIG. 1.

FIG. 3 is a plan view schematically illustrating a configuration of a gate driving part of the display apparatus of FIG. 1.

FIG. 4 is an equivalent circuit diagram illustrating a circuit structure disposed in a driving part included in the display apparatus of FIG. 1.

FIG. 5 is an equivalent circuit diagram illustrating a pixel circuit and an organic light emitting diode disposed in a pixel area of the display apparatus of FIG. 1.

FIG. 6 is a schematic cross-sectional view taken along line I-I′ of FIG. 1.

FIGS. 7 to 9 are schematic cross-sectional views illustrating an embodiment in which a gate driving part of the display apparatus of FIG. 1 is cut.

FIG. 10 is a schematic cross-sectional view illustrating an embodiment in which a gate driving part of the display apparatus of FIG. 1 is cut.

FIG. 11 is a schematic cross-sectional view illustrating an embodiment in which a gate driving part of the display apparatus of FIG. 1 is cut.

FIG. 12 is a schematic cross-sectional view illustrating an embodiment in which a gate driving part of the display apparatus of FIG. 1 is cut.

FIG. 13 is a schematic cross-sectional view illustrating an embodiment in which a gate driving part of the display apparatus of FIG. 1 is cut.

FIG. 14 is a schematic cross-sectional view illustrating an embodiment in which a gate driving part of the display apparatus of FIG. 1 is cut.

FIG. 15 is a schematic cross-sectional view illustrating an embodiment in which a gate driving part of the display apparatus of FIG. 1 is cut.

### DETAILED DESCRIPTION OF THE EMBODIMENTS

A display apparatus according to example embodiments will be described hereinafter with reference to the accompanying drawings, in which example embodiments are shown. Same or similar reference numerals may be used for same or similar elements in the drawings.

The disclosure may have various modifications and may be embodied in different forms, and example embodiments will be explained in detail with reference to the accompany drawings. The disclosure may, however, be embodied in different forms and should not be construed as limited to the embodiments set forth herein. Rather, all modifications, equivalents, and substitutes which are included in the spirit and technical scope of the disclosure should be included.

In the drawings, the dimensions of structures are exaggerated for clarity of illustration. It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element. As used herein, the singular forms are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or”.

The phrase “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” may modify the entire list of elements and may not modify the individual elements of the list.

It will be further understood that the terms “comprises,” “comprising,” “includes,” and/or “including,” “have” and/or “having” and variations thereof when used in this specification, specify the presence of stated features, numerals, steps, operations, elements, parts, or the combination thereof, but do not preclude the presence or addition of one or more other features, numerals, steps, operations, elements, parts, or the combination thereof.

It will also be understood that when a layer, a film, a region, a plate, etc. is referred to as being “on” or “above” another part, it can be “directly on” the other part, or intervening layers may also be present. It will also be understood that when a layer, a film, a region, a plate, etc. is referred to as being “under” or “below” another part, it can be “directly under” the other part, or intervening layers may also be present. When an element is referred to as being disposed “on” another element, it can be disposed under or below the other element.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

Additionally, the terms “overlap” or “overlapped” mean that a first object may be above or below or to a side of a second object, and vice versa. Additionally, the term “overlap” may include layer, stack, face or facing, extending over, covering or partly covering or any other suitable term as would be appreciated and understood by those of ordinary skill in the art. The terms “face” and “facing” mean that a first element may directly or indirectly oppose a second element. In a case in which a third element intervenes between the first and second element, the first and second element may be understood as being indirectly opposed to one another, although still facing each other. When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

It will be understood that when an element or layer is referred to as being “on”, “connected to” or “coupled to” another element or layer, it can be directly on, connected or coupled to the other element or layer or intervening elements or layers may be present.

The phrase “in a plan view” means viewing the object from the top, and the phrase “in a schematic cross-sectional view” means viewing a cross-section of which the object is vertically cut from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

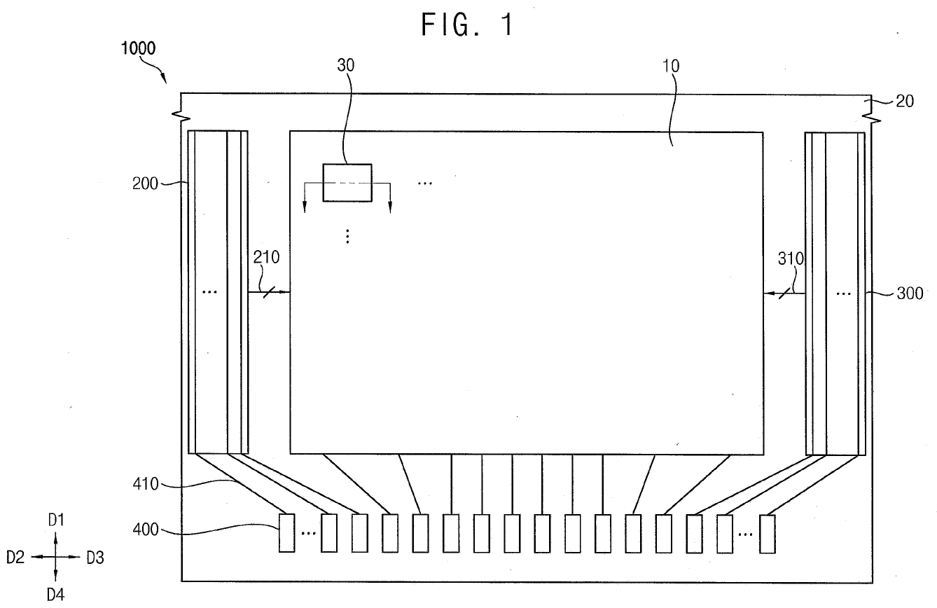

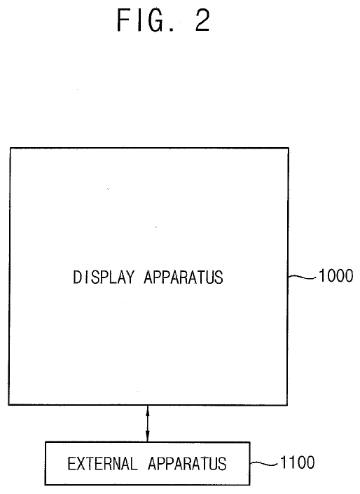

FIG. 1 is a plan view illustrating a display apparatus according to an embodiment of the disclosure, and FIG. 2 is a block diagram illustrating an external device electrically connected to the display apparatus of FIG. 1.

Referring to FIGS. 1 and 2, The display apparatus 1000 may include a gate driving part 200, a light emitting control driving part 300, a plurality of pad electrodes 400, and a plurality of wirings 410 electrically connected to the pad electrodes 400. The display apparatus 1000 may have a display part 10 and a peripheral part 20 positioned or disposed outside of the display part 10. For example, the peripheral part 20 may substantially surround or may be adjacent to the display part 10.

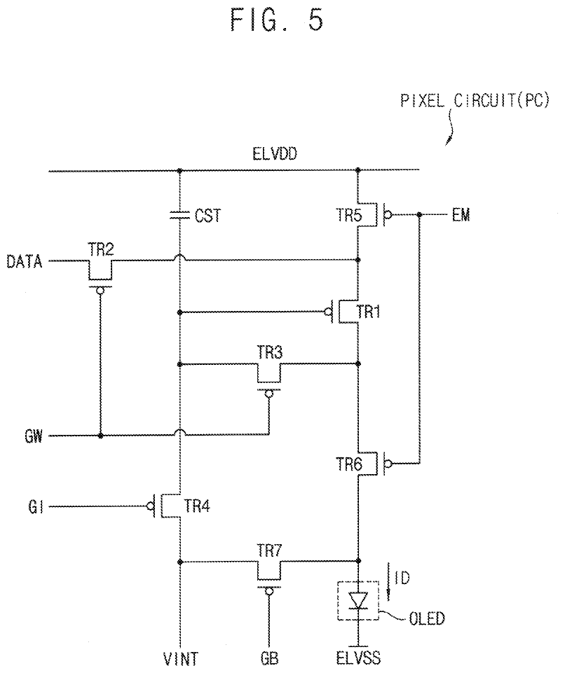

The display part 10 may include a plurality of pixel areas 30. The plurality of pixel areas 30 may be entirely arranged or disposed on the display part 10 in a matrix. For example, a pixel circuit PC illustrated in FIG. 5 may be disposed in each of the pixel areas 30, and an organic light emitting diode OLED may be disposed on the pixel circuit PC. An image may be displayed on the display part 10 through the pixel circuit PC and the organic light emitting diode OLED.

At least one driving transistor, at least one switching transistor, at least one capacitor, and the like may be disposed in each of the plurality of pixel areas 30. In an embodiment, one driving transistor (for example, a first transistor TR1 in FIG. 5) and six switching transistors (for example, second to seventh transistors TR2, TR3, TR4, TR5, TR6, TR7 in FIG. 5), one storage capacitor (for example, storage capacitor CST of FIG. 5), and the like may be disposed in each of the pixel areas 30.

However, although a shape of each of the display part 10, the pixel area 30, and the peripheral part 20 of the disclosure has been described as having a substantially rectangular planar shape, the shape is not limited thereto. For example, the shape of each of the display part 10, the pixel part 30, and the peripheral part 20 may have a substantially polygonal planar shape, a substantially circular planar shape, or a substantially elliptical planar shape.

A plurality of wirings 410 may be disposed on the peripheral part 20. For example, the wirings 410 may include a data signal wiring, a gate signal wiring, a light emitting control signal wiring, a gate initialization signal wiring, an initialization voltage wiring, and a power voltage wiring. The wirings 410 may extend from the pad electrodes 400 to the display part 10 to be electrically connected to the pixel circuit PC and the organic light emitting diode OLED. For example, the wirings 410 may extend from the pad electrodes 400 to the gate driving part 200 and the light emitting control driving part 300 to be electrically connected to the gate driving part 200 and the light emitting control driving part 300. In an embodiment, the gate driving part 200 may provide gate signals 210 to the display part 10, and the light emitting control driving part 300 may provide emitting signals 310 to the display part 10.

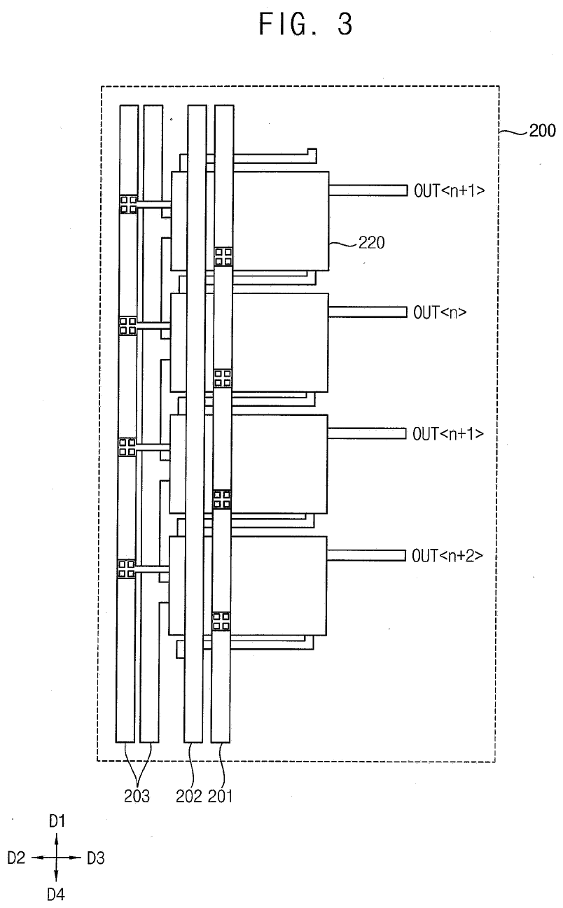

For example, the pad electrodes 400 may be disposed in the peripheral part 20 positioned in the fourth direction DR4 of the display part 10. As illustrated in FIG. 3, the external apparatus 1100 may be electrically connected to the display apparatus 1000 through a flexible printed circuit board or a printed circuit board. For example, one or a side of the flexible printed circuit board may directly electrically contact the pad electrodes 400, and the other side of the flexible printed circuit board may directly electrically contact the external apparatus 1100. The external apparatus 1100 may generate a data signal, a gate signal, a light emitting control signal, a gate initialization signal, an initialization voltage, a power voltage, and the like within the spirit and the scope of the disclosure. The data signal, the gate signal, the light emitting control signal, the gate initialization signal, the initialization voltage, the power supply voltage, and the like may be provided to the pixel circuit PC and the organic light emitting diode OLED through the pad electrodes 400 and the flexible printed circuit board. For example, a driving integrated circuit may be mounted on the flexible printed circuit board. In an embodiment, the driving integrated circuit may be mounted on the display apparatus 1000 adjacent to the pad electrodes 400.

In an embodiment, the gate driving part 200 may be disposed in the peripheral part 20 positioned in the second direction DR2 of the display part 10. The light emitting control driving part 300 may be disposed in the peripheral part 20 located in the third direction DR3 of the display part 10. In an embodiment, the gate driving part 200 and the light emitting control driving part 300 may be disposed together in the second direction DR2 or the third direction DR3 of the display part 10. For example, the gate driving part 200 may be positioned adjacent to the display part 10 rather than the light emitting control driving part 300. In an embodiment, the gate driving part 200 and the light emitting control driving part 300 may be disposed in the first direction DR1 of the display part 10, and the light emitting control driving part 300 may be positioned more adjacent to the display part 10 than the gate driving part 200.

FIG. 3 is a plan view schematically illustrating a configuration of a gate driving part of the display apparatus of FIG. 1.

Referring to FIGS. 1 and 3, the gate driving part 200 may include first to nth shift registers 220 (where n is a natural number greater than or equal to 2). As an example, the gate driving part 200 may include a first signal wiring 201 and a second signal wiring 202 overlapping the shift registers 220, respectively.

The first signal wiring 201 may extend in the first direction D1. In an embodiment, the first signal wiring 201 may overlap a driving part transistor included in the shift register 220. The first signal wiring 201 may be electrically connected to the driving part transistor through a contact hole. For example, in an embodiment, a first driving signal may be applied to the first signal wiring 201. For example, the first driving signal may be a constant voltage. The first driving signal may include a first driving voltage VGH and a second driving voltage VGL. As a constant voltage is applied to the first signal wiring 201, a coupling phenomenon may not occur between the first signal wiring 201 and the driving part transistor.

The second signal wiring 202 may extend in the first direction D1. In an embodiment, the second signal wiring 202 may overlap a driving part transistor included in the shift register 220. Also, in an embodiment, a second driving signal may be applied to the second signal wiring 202. The second driving signal may be a start signal FLM. The start signal FLM may be transmitted to a first shift register positioned at the end of the first direction D1 among the shift registers 200. As the start signal FLM having a long period is applied to the second signal wiring 202, a coupling phenomenon may not occur between the second signal wiring 202 and the driving part transistor.

The clock signal wiring 203 may be disposed in the second direction D2 of the shift register 220. A clock signal may be applied to the clock signal wiring 203. In an embodiment, the clock signal wiring 203 and the shift register 220 may be electrically connected by a bridge electrode.

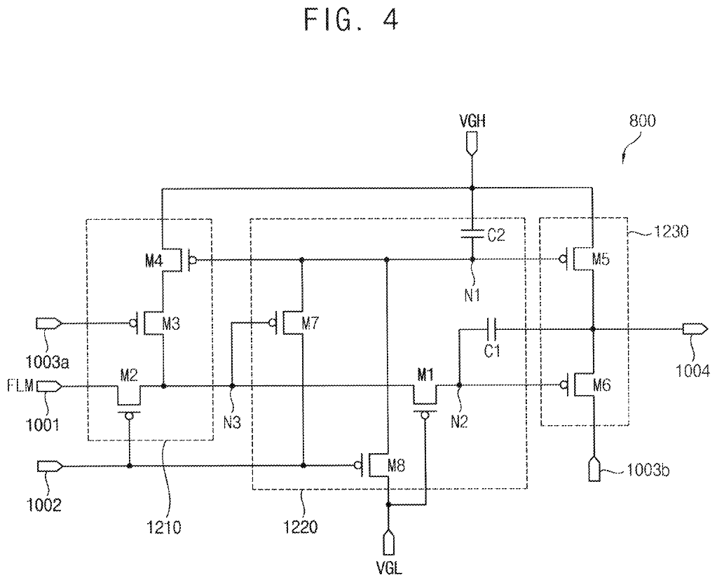

FIG. 4 is an equivalent circuit diagram illustrating a circuit structure disposed in a driving part included in the display apparatus of FIG. 1.

Referring to FIGS. 1 and 4, the gate driving part 200 may include a circuit structure 800. The gate driving part 200 may receive the gate signal from the external device 1100, and the gate signal may be provided to the pixel circuit PC through circuit structures 800 of the gate driving part 200.

The circuit structure 800 may include at least one transistor and at least one capacitor. For example, the circuit structure 800 may include first to eighth transistors M1, M2, M3, M4, M5, M6, M7, M8, and first and second capacitors C1 and C2. However, the configuration of the circuit structure 800 of the disclosure is not limited thereto, and the circuit structure 800 may be variously configured within a range for generating a gate signal.

The circuit structure 800 may include a first driving area 1210, a second driving area 1220, and an output area 1230.

The first driving area 1210 may include a second transistor M2, a third transistor M3, and a fourth transistor M4. The first driving area 1210 may control a voltage of the third node N3 based on signals supplied to the first input terminal 1001, the second input terminal 1002, and the 3-a input terminal 1003a. In an embodiment, the start signal FLM may be applied to the first input terminal 1001. For example, in an embodiment, the clock signal may be applied to the second input terminal 1002 and the 3-a input terminal 1003a. The second transistor M2 may electrically connect the first input terminal 1001 and the third node N3, and a gate electrode of the second transistor M2 may be electrically connected to the second input terminal 1002. The second transistor M2 may control a connection between the first input terminal 1001 and the third node N3 based on a clock signal supplied to the second input terminal 1002. The third transistor M3 and the fourth transistor M4 may be electrically connected in series between the third node N3 and a first driving voltage wiring. The third transistor M3 may electrically connect the fourth transistor M4 and the third node N3, and a gate electrode of the third transistor M3 may be electrically connected to the 3-a input terminal 1003a. The third transistor M3 may control a connection between the fourth transistor M4 and the third node N3 based on a clock signal supplied to the 3-a input terminal 1003a. The fourth transistor M4 may electrically connect the third transistor M3 and the first driving voltage wiring, and a gate electrode of the fourth transistor M4 may be electrically connected to the first node N1. The fourth transistor M4 may control a connection between the third transistor M3 and the first driving voltage wiring based on a voltage of the first node N1.

The second driving area 1220 may include a seventh transistor M7, an eighth transistor M8, a first capacitor C1, and a second capacitor C2. The second driving area 1220 may control a voltage of the first node N1 based on the voltages of the second input terminal 1002 and the third node N3. The first capacitor C1 may be electrically connected between the second node N2 and the output terminal 1004. The first capacitor C1 may charge voltages based on turn-on and turn-off of the sixth transistor M6. The second capacitor C2 may be electrically connected between the first node N1 and the first driving voltage wiring. The second capacitor C2 may charge a voltage applied to the first node N1. The seventh transistor M7 may electrically connect the first node N1 and the second input terminal 1002, and a gate electrode of the seventh transistor M7 may be electrically connected to the third node N3. The seventh transistor M7 may control a connection between the first node N1 and the second input terminal 1002 based on the voltage of the third node N3. The eighth transistor M8 may electrically connect the first node N1 and a second driving voltage wiring, and a gate electrode of the eighth transistor M8 may be electrically connected to the second input terminal 1002. The eighth transistor M8 may control a connection between the first node N1 and the second driving voltage wiring based on a clock signal of the second input terminal 1002. The first transistor M1 may electrically connect the third node N3 and the second node N2, and the gate electrode of the first transistor M1 may be electrically connected to the second driving voltage wiring. The first transistor M1 may maintain an electrical connection between the third node N3 and the second node N2 while maintaining the turned-on state. Optionally, the first transistor M1 may limit a voltage drop width of the third node N3 based on the voltage of the second node N2.

The output area 1230 may include the fifth transistor M5 and the sixth transistor M6. The output area 1230 may control a voltage supplied to the output terminal 1004 based on the voltage of the first node N1 and the voltage of the second node N2. The fifth transistor M5 may electrically connect the first driving voltage wiring and the output terminal 1004, and a gate electrode of the fifth transistor M5 may be electrically connected to the first node N1. The fifth transistor M5 may control a connection between the first driving voltage wiring and the output terminal 1004 based on the voltage applied to the first node N1.

The sixth transistor M6 may electrically connect the output terminal 1004 and the 3-a input terminal 1003a, and a gate electrode of the sixth transistor M6 may be electrically connected to the second node N2. The sixth transistor M6 may control a connection between the output terminal 1004 and a 3-b input terminal 1003b based on the voltage applied to the second node N2. The output area 1230 may be driven as a buffer. In an embodiment, a clock signal may be applied to the 3-b input terminal 1003b.

Accordingly, the circuit structure 800 may output a gate signal (for example, a gate signal GW of FIG. 5) to the output terminal 1004. However, this is exemplary, and a signal that can be output by the circuit structure 800 is not limited thereto. For example, the circuit structure 800 may output a gate initialization signal GI of FIG. 5 to the output terminal 1004. For example, the circuit structure 800 may output a diode initialization signal GB of FIG. 5 to the output terminal 1004.

Although the circuit structure 800 has been described as including eight transistors and two capacitors, the configuration of the disclosure is not limited thereto. For example, the circuit structure 800 may have a configuration including at least one transistor and at least one capacitor.

FIG. 5 is an equivalent circuit diagram illustrating a pixel circuit and an organic light emitting diode disposed in a pixel area of the display apparatus of FIG. 1.

Referring to FIGS. 1 and 5, A pixel circuit PC and an organic light emitting diode OLED may be disposed in each of the pixel areas 30. The pixel circuit PC may include first to seventh transistors TR1, TR2, TR3, TR4, TR5, TR6, and TR7, a storage capacitor CST, a high power voltage wiring, a low power voltage wiring, an initialization voltage wiring, a data signal wiring, a gate signal wiring, a gate initialization signal wiring, a light emitting control signal wiring, a diode initialization signal, and the like within the spirit and the scope of the disclosure. The first transistor TR1 may correspond to a driving transistor, and the second to seventh transistors TR2, TR3, TR4, TR5, TR6, and TR7 may correspond to a switching transistor. Each of the first to seventh transistors TR1, TR2, TR3, TR4, TR5, TR6, and TR7 may include a first terminal, a second terminal, a channel, and a gate terminal. In an embodiment, the first terminal may be a source terminal and the second terminal may be a drain terminal. Optionally, the first terminal may be a drain terminal, and the second terminal may be a source terminal.

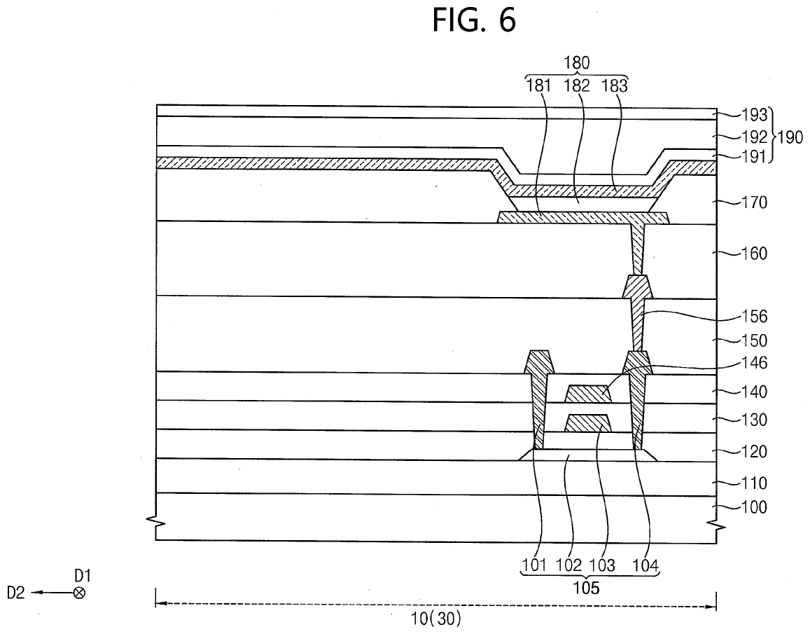

The organic light emitting diode OLED may output light based on a driving current ID. The organic light emitting diode OLED may include a first terminal and a second terminal. In an embodiment, the second terminal of the organic light emitting diode OLED may be supplied with the low power voltage ELVSS, and the first terminal of the organic light emitting diode OLED may be supplied with the high power voltage ELVDD. For example, the first terminal of the organic light emitting diode OLED may be an anode terminal, and the second terminal of the organic light emitting diode OLED may be a cathode terminal. Optionally, the first terminal of the organic light emitting diode OLED may be a cathode terminal, and the second terminal of the organic light emitting diode OLED may be an anode terminal. In an embodiment, the anode terminal of the organic light emitting diode OLED may correspond to a first electrode 181 of FIG. 6, and the cathode terminal of the organic light emitting diode OLED may correspond to a second electrode 183 of FIG. 6.

The first transistor TR1 may generate the driving current ID. For example, the first transistor TR1 may generate the driving current ID based on a voltage difference between the gate terminal and the source terminal. For example, a gray scale may be expressed based on a magnitude of the driving current ID supplied to the organic light emitting diode OLED.

The gate terminal of the second transistor TR2 may receive the gate signal GW. The first terminal of the second transistor TR2 may receive the data signal DATA. The second terminal of the second transistor TR2 may be electrically connected to the first terminal of the first transistor TR1. The second transistor TR2 may supply the data signal DATA to the first terminal of the first transistor TR1 during an activation period of the gate signal GW.

The gate terminal of the third transistor TR3 may receive the gate signal GW. The first terminal of the third transistor TR3 may be electrically connected to the gate terminal of the first transistor TR1. The second terminal of the third transistor TR3 may be electrically connected to the second terminal of the first transistor TR1. The third transistor TR3 may electrically connect the gate terminal of the first transistor TR1 and the second terminal of the first transistor TR1 during an activation period of the gate signal GW. For example, the third transistor TR3 may diode-connect the first transistor TR1 during the activation period of the gate signal GW.

An initialization voltage VINT may be applied to an initialization voltage wiring. An input terminal of the initialization voltage wiring may be electrically connected to a first terminal of the fourth transistor TR4 and a first terminal of the seventh transistor TR7. An output terminal of the initialization voltage wiring may be electrically connected to a second terminal of the fourth transistor TR4 and a first terminal of the storage capacitor CST.

A gate terminal of the fourth transistor TR4 may receive a gate initialization signal GI. A first terminal of the fourth transistor TR4 may receive the initialization voltage VINT. A second terminal of the fourth transistor TR4 may be electrically connected to a gate terminal of the first transistor TR1.

The fourth transistor TR4 may supply the initialization voltage VINT to the gate terminal of the first transistor TR1 during an activation period of the gate initialization signal GI. For example, the fourth transistor TR4 may initialize the gate terminal of the first transistor TR1 to the initialization voltage VINT during the activation period of the gate initialization signal GI.

The gate terminal of the fifth transistor TR5 may receive the light emitting control signal EM. The first terminal of the fifth transistor TR5 may be electrically connected to the high power voltage wiring. The second terminal of the fifth transistor TR5 may be electrically connected to the first terminal of the first transistor TR1. The fifth transistor TR5 may supply the high power voltage ELVDD to the first terminal of the first transistor TR1 during an activation period of the emission control signal EM. Conversely, the fifth transistor TR5 may cut off the supply of the high power voltage ELVDD during an inactive period of the light emitting control signal EM. The fifth transistor TR5 may supply the high power voltage ELVDD to the first terminal of the first transistor TR1 during an activation period of the light emitting control signal EM. Accordingly, the first transistor TR1 may generate the driving current ID. Also, the fifth transistor TR5 may cut off the supply of the high power voltage ELVDD during the inactive period of the light emitting control signal EM. Accordingly, the data signal DATA supplied to the first terminal of the first transistor TR1 may be supplied to the gate terminal of the first transistor TR1.

The gate terminal of the sixth transistor TR6 may receive the light emitting control signal EM. The first terminal of the sixth transistor TR6 may be electrically connected to the second terminal of the first transistor TR1. The second terminal of the sixth transistor TR6 may be electrically connected to the first terminal of the organic light emitting diode OLED. The sixth transistor TR6 may supply the driving current ID generated by the first transistor TR1 to the organic light emitting diode OLED during the activation period of the light emitting control signal EM. Accordingly, the organic light emitting diode OLED may output light.

The gate terminal of the seventh transistor TR7 may receive a diode initialization signal GB. The first terminal of the seventh transistor TR7 may receive the initialization voltage VINT. The second terminal of the seventh transistor TR7 may be electrically connected to the first terminal of the organic light emitting diode OLED. The seventh transistor TR7 may supply the initialization voltage VINT to the first terminal of the organic light emitting diode OLED during an activation period of the diode initialization signal GB.

The storage capacitor CST may include a first terminal and a second terminal. The storage capacitor CST may be electrically connected between the high power voltage wiring and the gate terminal of the first transistor TR1. For example, the first terminal of the storage capacitor CST may be electrically connected to the gate terminal of the first transistor TR1, and the second terminal of the storage capacitor CST may be electrically connected to the high power voltage wiring. The storage capacitor CST may maintain the voltage level of the gate terminal of the first transistor TR1 during the inactive period of the gate signal GW.

However, although it has been described that the pixel circuit PC of the disclosure may include seven transistors and one storage capacitor, the configuration of the disclosure is not limited thereto. For example, the pixel circuit PC may have a configuration including at least one transistor and at least one storage capacitor.

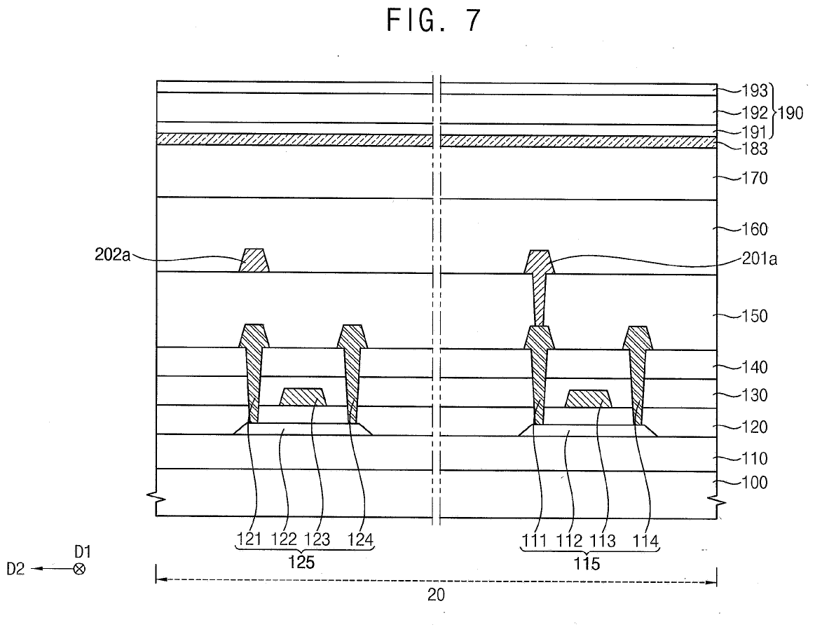

FIG. 6 is a schematic cross-sectional view taken along line I-I′ of FIG. 1, and FIGS. 7 to 9 are schematic cross-sectional views illustrating an embodiment in which a gate driving part of the display apparatus of FIG. 1 is cut. However, contents to be described below are not limited to the gate driving part 200 and may be equally applied to the light emitting control driving part 300.

Referring to FIGS. 6 and 7, the display apparatus 1000 may include a substrate 100, a buffer layer 110, a pixel driving transistor 105, a first driving part transistor 115, a second driving part transistor 125, a first gate insulating layer 120, a second gate insulating layer 130, interlayer insulating layer 140, first via insulating layer 150, second via insulating layer 160, pixel defining layer 170, light emitting structure or element 180, thin film encapsulation structure 190, and the like within the spirit and the scope of the disclosure. Here, the pixel driving transistor 105 may include an active layer 102, a gate electrode 103, a source electrode 101, and a drain electrode 104. The first driving part transistor 115 may include a first active pattern 112, a first gate pattern 113, a first source pattern 111 and a first drain pattern 114, and a second driving part transistor 125 may include a second active pattern 122, a second gate pattern 123, a second source pattern 121, and a second drain pattern 124. The light emitting structure element 180 may include a first electrode 181, a light emitting layer 182, and a second electrode 183, and the thin film encapsulation structure 190 may include a first inorganic thin film encapsulation layer 191, an organic thin film encapsulation layer 192 and a second inorganic thin film encapsulation layer 193.

A substrate 100 comprising transparent material or opaque materials may be provided. The substrate 100 may be formed of a flexible transparent resin substrate. For example, the substrate 100 may have a configuration in which a first organic layer, a first barrier layer, a second organic layer, and a second barrier layer may be sequentially stacked. The first barrier layer and the second barrier layer may include an inorganic material such as silicon oxide, and may block moisture and/or moisture penetrating through the first and second organic layers. For example, the first organic layer and the second organic layer may include an organic material such as a polyimide resin, and may have flexibility.

Optionally, the substrate 100 may include a quartz substrate, a synthetic quartz substrate, a calcium fluoride substrate, a fluorine-doped quartz substrate, a soda lime glass substrate, a non-alkali glass substrate, and the like within the spirit and the scope of the disclosure.

However, although it has been described that the substrate 100 has four layers, the configuration of the disclosure is not limited thereto. For example, in an embodiment, the substrate 100 may be composed of a single layer or a plurality of layers.

The buffer layer 110 may be disposed on the substrate 100. The buffer layer 110 may be entirely disposed on the display part 10 and the peripheral part 20 on the substrate 100. Depending on the type of the substrate 100, two or more buffer layers 110 may be provided or disposed on the substrate 100 or the buffer layer 110 may not be disposed. The buffer layer 110 may include a silicon compound, a metal oxide, or the like within the spirit and the scope of the disclosure. For example, the buffer layer 110 may include silicon oxide (SiO), silicon nitride (SiN), silicon oxynitride (SiON), silicon oxycarbide (SiOC), silicon carbonitride (SiCN), aluminum oxide (AlO), aluminum nitride (AlN), tantalum oxide (TaO), hafnium oxide (HfO), zirconium oxide (ZrO), titanium oxide (TiO), and the like within the spirit and the scope of the disclosure.

The active layer 102 may be disposed on the display part 10 on the buffer layer 110, and the first active pattern 112 and the second active pattern 122 may be disposed on the peripheral part 20 on the buffer layer 110. Each of the active layer 102, the first active pattern 112 and the second active pattern 122 may include an oxide semiconductor, an inorganic semiconductor (for example, amorphous silicon, poly silicon), or an organic semiconductor. Each of the active layer 102, the first active pattern 112, and the second active pattern 122 may have a source area, a drain area, and a channel area positioned between the source area and the drain area. In an embodiment, the display apparatus 1000 may include a separate active layer including an oxide. In this case, the display apparatus 1000 may include an oxide transistor including the separate active layer.

The first gate insulating layer 120 may be disposed on the active layer 102, the first active pattern 112, and the second active pattern 122. The first gate insulating layer 120 may cover or overlap the active layer 102 in the display part 10 on the buffer layer 110. For example, the first gate insulating layer 120 may extend from the display part 10 to the peripheral part 20 to cover or overlap the first active pattern 112 and the second active pattern 122. For example, the first gate insulating layer 120 may sufficiently cover or overlap the active layer 102, the first active pattern 112, and the second active pattern 122 on the buffer layer 110. In this case, the first gate insulating layer 120 may have a substantially flat top surface without generating a level difference around the active layer 102, the first active pattern 112, and the second active pattern 122. Optionally, the first gate insulating layer 120 may have a uniform thickness and may be disposed along the profiles of the active layer 102, the first active pattern 112, and the second active pattern 122. The first gate insulating layer 120 may include a silicon compound, a metal oxide, or the like within the spirit and the scope of the disclosure. In an embodiment, the first gate insulating layer 120 may have a multilayer structure including a plurality of insulating layers. The insulating layers may have different materials and different thicknesses.

The gate electrode 103 may be disposed on the display part 10 on the first gate insulating layer 120. The first gate pattern 113 and the second gate pattern 123 may be disposed in the peripheral part 20 on the first gate insulating layer 120. The gate electrode 103 may be disposed on area of the first gate insulating layer 120 where the active layer 102 is positioned below. For example, the gate electrode 103 may be disposed to overlap the channel area of the active layer 102. The first gate pattern 113 may be disposed on area of the first gate insulating layer 120 where the first active pattern 112 may be positioned or disposed below. For example, the first gate pattern 113 may be disposed to overlap the channel area of the first active pattern 112. The second gate pattern 123 may be disposed on area of the first gate insulating layer 120 where the second active pattern 122 is positioned below. For example, the second gate pattern 123 may be disposed to overlap the channel area of the second active pattern 122. Each of the gate electrode 103, the first gate pattern 113, and the second gate pattern 123 may include a metal, an alloy, a metal nitride, a conductive metal oxide, a transparent conductive material, and the like within the spirit and the scope of the disclosure. These may be used alone or in combination with each other. In an embodiment, each of the gate electrode 103, the first gate pattern 113, and the second gate pattern 123 may have a multilayer structure including a plurality of metal layers. The metal layers may have different materials and different thicknesses.

The second gate insulating layer 130 may be disposed on the gate electrode 103, the first gate pattern 113, and the second gate pattern 123. The second gate insulating layer 130 may cover or overlap the gate electrode 103 in the display part 10 on the first gate insulating layer 120. For example, the second gate insulating layer 130 may extend from the display part 10 to the peripheral part 20 to cover or overlap the first gate pattern 113 and the second gate pattern 123. For example, the second gate insulating layer 130 may sufficiently cover or overlap the gate electrode 103, the first gate pattern 113, and the second gate pattern 123 on the first gate insulating layer 120. In this case, the second gate insulating layer 130 may have a substantially flat top surface without generating level difference around the gate electrode 103, the first gate pattern 113, and the second gate pattern 123. Optionally, the second gate insulating layer 130 may have a uniform thickness and may be disposed along the profiles of the gate electrode 103, the first gate pattern 113, and the second gate pattern 123. The second gate insulating layer 130 may include a silicon compound, a metal oxide, or the like within the spirit and the scope of the disclosure. In an embodiment, the second gate insulating layer 130 may have a multilayer structure including a plurality of insulating layers. The insulating layers may have different materials and different thicknesses.

A capacitor electrode 146 may be disposed in the display part 10 on the second gate insulating layer 130. The capacitor electrode 146 may overlap the gate electrode 103. The capacitor electrode 146 may include a metal, an alloy, a metal nitride, a conductive metal oxide, a transparent conductive material, or the like within the spirit and the scope of the disclosure. These may be used alone or in combination with each other.

The interlayer insulating layer 140 may be disposed on the capacitor electrode 146. The interlayer insulating layer 140 may cover or overlap the capacitor electrode 146 in the display part 10 on the second gate insulating layer 130. For example, the interlayer insulating layer 140 may extend from the display part 10 to the peripheral part 20. For example, the interlayer insulating layer 140 may sufficiently cover or overlap the capacitor electrode 146 on the second gate insulating layer 130. In this case, the interlayer insulating layer 140 may have a substantially flat top surface without generating level difference around the capacitor electrode 146. Optionally, the interlayer insulating layer 140 may be disposed along the profile of the capacitor electrode 146 with a uniform thickness on the second gate insulating layer 130. The interlayer insulating layer 140 may include a silicon compound, a metal oxide, or the like within the spirit and the scope of the disclosure. In an embodiment, the interlayer insulating layer 140 may have a multilayer structure including a plurality of insulating layers. The insulating layers may have different materials and different thicknesses.

The source electrode 101 and the drain electrode 104 may be disposed in the display part 10 on the interlayer insulating layer 140. A first source pattern 111, a first drain pattern 114, a second source pattern 121, and a second drain pattern 124 may be disposed in the peripheral part 20 on the interlayer insulating layer 140. The source electrode 101 may be electrically connected to the source area of the active layer 102 through a contact hole, and the drain electrode 104 may be electrically connected to the drain area of the active layer 102 through a contact hole. The first source pattern 111 may be electrically connected to the source area of the first active pattern 112 through a contact hole, and the first drain pattern 114 may be electrically connected to the drain area of the first active pattern 112 through a contact hole. The second source pattern 121 may be electrically connected to the source area of the second active pattern 122 through a contact hole, and the second drain pattern 124 may be electrically connected to the drain area of the second active pattern 122 through a contact hole.

Each of the source electrode 101, the drain electrode 104, the first source pattern 111, the first drain pattern 114, the second source pattern 121 and the second drain pattern 124 may include a metal, an alloy, a metal nitride, a conductive metal oxide, a transparent conductive material, and the like within the spirit and the scope of the disclosure. These may be used alone or in combination with each other. In an embodiment, each of the source electrode 101, the drain electrode 104, the first source pattern 111, the first drain pattern 114, the second source pattern 121 and the second drain pattern 124 may have a multilayer structure including a plurality of metal layers. The metal layers may have different materials and different thicknesses.

Accordingly, the pixel driving transistor 105 including the active layer 102, the gate electrode 103, the source electrode 101, and the drain electrode 104 may be disposed. A first driving part transistor 115 including the first active pattern 112, the first gate pattern 113, the first source pattern 111, and the first drain pattern 114 may be disposed. For example, a second driving part transistor 125 including the second active pattern 122, the second gate pattern 123, the second source pattern 121, and the second drain pattern 124 may be disposed. For example, the first driving part transistor 115 may correspond to the fifth transistor M5 of FIG. 4, and the pixel driving transistor 105 may correspond to the sixth transistor TR6 of FIG. 5.

The first via insulating layer 150 may be disposed on the source electrode 101, the drain electrode 104, the first source pattern 111, the first drain pattern 114, the second source pattern 121, and the second drain pattern 124. The first via insulating layer 150 may cover or overlap the source electrode 101, the drain electrode 104, the first source pattern 111, the first drain pattern 114, the second source pattern 121, and the second drain pattern 124.

The first via insulating layer 150 may be disposed to have a relatively thick thickness in the display part 10 and the peripheral part 20. In this case, the first via insulating layer 150 may have a substantially flat top surface. To this end, a planarization process may be added to the first via insulating layer 150 in order to implement a flat top surface of the first via insulating layer 150. Optionally, the first via insulating layer 120 may have a uniform thickness and may be disposed along the profiles of the source electrode 101, the drain electrode 104, the first source pattern 111, the first drain pattern 114, the second source pattern 121, and the second drain pattern 124. The first via insulating layer 150 may be made of an organic material or an inorganic material. In an embodiment, the first via insulating layer 150 may include an organic material. For example, the first via insulating layer 150 may include a photoresist, a polyacrylic resin, a polyimide resin, a polyamide resin, a siloxane resin, an acrylic resin, an epoxy resin, or the like within the spirit and the scope of the disclosure.

A connection electrode 156 may be disposed on the display part 10 on the first via insulating layer 150. A first signal wiring 201a and a second signal wiring 202a may be disposed in the peripheral part 20 on the first via insulating layer 150. In an embodiment, the connection electrode 156 may electrically connect the light emitting structure or element 180 and the pixel driving transistor 105. The first signal wiring 201a disposed on the same layer as the connection electrode 156 may be electrically connected to the first source pattern 111 through a contact hole. In an embodiment, the first signal wiring 201a and the second signal wiring 202a may extend in the first direction D1. The first signal wiring 201a and the second signal wiring 202a may be disposed to be spaced apart in a second direction D2 perpendicular to the first direction D1. In an embodiment, a constant voltage may be applied to the first signal wiring 201a. The constant voltage may include a first driving voltage VGH and a second driving voltage VGL. The first driving voltage VGH may have a higher voltage level than the second driving voltage VGL. In an embodiment, the start signal FLM may be applied to the second signal wiring 202a. The start signal FLM may have activation sections of different lengths according to a driving frequency. For example, as the driving frequency is smaller, the length of the activation section of the start signal FLM may be longer.

In an embodiment, the first signal wiring 201a may overlap the first source pattern 111, and the second signal wiring 202a may overlap the second source pattern 121. However, this is an example, and the arrangement of the first and second signal wirings 201a and 202a is not limited thereto. According to an embodiment, the second signal wiring 202a may overlap the second gate pattern 123 or may overlap the second drain pattern 124.

Each of the first and second signal wirings 201a and 202a may include a metal, an alloy, a metal nitride, a conductive metal oxide, a transparent conductive material, and the like within the spirit and the scope of the disclosure. These may be used alone or in combination with each other.

In related art, the first signal wiring 201a and the second signal wiring 202a may be disposed on the same layer as the source electrode 101 in the peripheral part 20 of the display apparatus 1000. In the display apparatus 1000 according to an embodiment, since the first signal wiring 201a and the second signal wiring 202a may be disposed above the source electrode 101 or the like, the dead space in the second direction D2 may be reduced. Also, the overall length of the signal wiring may be reduced, so that the resistance may decrease.

A coupling phenomenon may not occur between the first signal wiring 201a and the first driving part transistor 115 according to the characteristic of the constant voltage to which the voltage is constantly supplied. For example, according to the characteristics of the start signal FLM having a long signal period, a coupling phenomenon may not occur between the second signal wiring 202a and the second driving part transistor 125.

The second via insulating layer 160 may be disposed on the first via insulating layer 150. The second via insulating layer 160 may cover or overlap the connection electrode 156 in the display part 10. For example, the second via insulating layer 160 may cover or overlap the first signal wiring 201a and the second signal wiring 202a in the peripheral part 20.

The second via insulating layer 160 may be disposed in a relatively thick thickness on the display part 10 and the peripheral part 20. In this case, the second via insulating layer 160 may have a substantially flat top surface. A planarization process may be added to the second via insulating layer 160 in order to implement a flat top surface of the second via insulating layer 160. Optionally, the second via insulating layer 160 may be disposed at a uniform thickness in the display part 10 and the peripheral part 20 on the interlayer insulating layer 140. In this case, the second via insulating layer 160 may be disposed along the profile of the connection electrode 156, the first signal wiring 201a, and the second signal wiring 202a.

The second via insulating layer 160 may be made of an organic material or an inorganic material. In an embodiment, the second via insulating layer 160 may include an organic material. For example, the second via insulating layer 160 may include a photoresist, a polyacrylic resin, a polyimide resin, a polyamide resin, a siloxane resin, an acrylic resin, an epoxy resin, or the like within the spirit and the scope of the disclosure.

The first electrode 181 may be disposed on the display part 10 on the second via insulating layer 160. The first electrode 181 may be electrically connected to the connection electrode 156 through a contact hole formed by removing a part of the second via insulating layer 160, and the first electrode 181 may be electrically connected to the pixel driving transistor 105. The first electrode 181 may include a metal, an alloy, a metal nitride, a conductive metal oxide, a transparent conductive material, or the like within the spirit and the scope of the disclosure. These may be used alone or in combination with each other. In an embodiment, the first electrode 181 may have a multilayer structure including a plurality of metal layers. The metal layers may have different materials and different thicknesses.

The pixel defining layer 170 may expose a part of the first electrode 181 and may extend from the display part 10 to the peripheral portion 20 and may be disposed. The pixel defining layer 170 may be disposed while exposing a part of the first electrode 181. The pixel defining layer 170 may be disposed extending from the display part 10 to the peripheral part 20. The pixel defining layer 170 may be made of an organic material or an inorganic material. In an embodiment, the pixel defining layer 170 may include an organic material.

The light emitting layer 182 may be disposed on the first electrode 181 partially exposed by the pixel defining layer 170 in the display part 10. The second electrode 183 may be disposed on the pixel defining layer 170 and the light emitting layer 182. The second electrode 183 may include a metal, an alloy, a metal nitride, a conductive metal oxide, a transparent conductive material, or the like within the spirit and the scope of the disclosure. These may be used alone or in combination with each other.

Accordingly, the light emitting structure or element 180 including the first electrode 181, the light emitting layer 182, and the second electrode 183 may be disposed.

The first inorganic thin film encapsulation layer 191 may be disposed on the display part 10 on the second electrode 183 and the peripheral part 20. The first inorganic thin film encapsulation layer 191 may prevent the light emitting structure or element 180 from deteriorating due to penetration of moisture or oxygen. For example, the first inorganic thin film encapsulation layer 191 may also perform a function of protecting the light emitting structure or element 180 from external impact. The first inorganic thin film encapsulation layer 191 may include inorganic materials having flexibility.

The organic thin film encapsulation layer 192 may be disposed on the display part 10 and the peripheral part 20 on the first inorganic thin film encapsulation layer 191. The organic thin film encapsulation layer 192 may improve a flatness of the display apparatus 1000 and protect the light emitting structure or element 180. The organic thin film encapsulation layer 192 may include organic materials having flexibility.

The second inorganic thin film encapsulation layer 193 may be disposed on the organic thin film encapsulation layer 192. The second inorganic thin film encapsulation layer 193 may cover or overlap the organic thin film encapsulation layer 192 and may be disposed along the profile of the organic thin film encapsulation layer 192 with a uniform thickness. The second inorganic thin film encapsulation layer 193 together with the first inorganic thin film encapsulation layer 191 may prevent the light emitting structure or element 180 from deteriorating due to penetration of moisture or oxygen. For example, the second inorganic thin film encapsulation layer 193 may also perform a function of protecting the light emitting structure or element 180 together with the first inorganic thin film encapsulation layer 191 and the organic thin film encapsulation layer 192 from external impact. The second inorganic thin film encapsulation layer 193 may include inorganic materials having flexibility.

Accordingly, the thin film encapsulation structure 190 including the first inorganic thin film encapsulation layer 191, the organic thin film encapsulation layer 192 and the second inorganic thin film encapsulation layer 193 may be disposed.

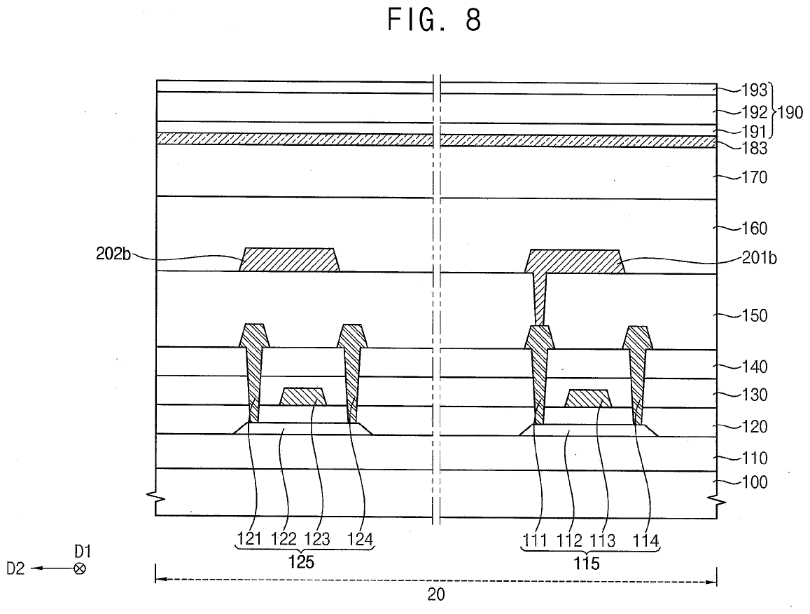

Referring to FIG. 8, the first signal wiring 201b may overlap the first source pattern 111 and the first gate pattern 113, and the second signal wiring 202b may overlap the second source pattern 121 and the second gate pattern 123. For example, the second signal wiring 202b may overlap the second source pattern 121 and the second gate pattern 123, and the second signal wiring 202b may overlap the second drain pattern 124 and the second gate pattern 123.

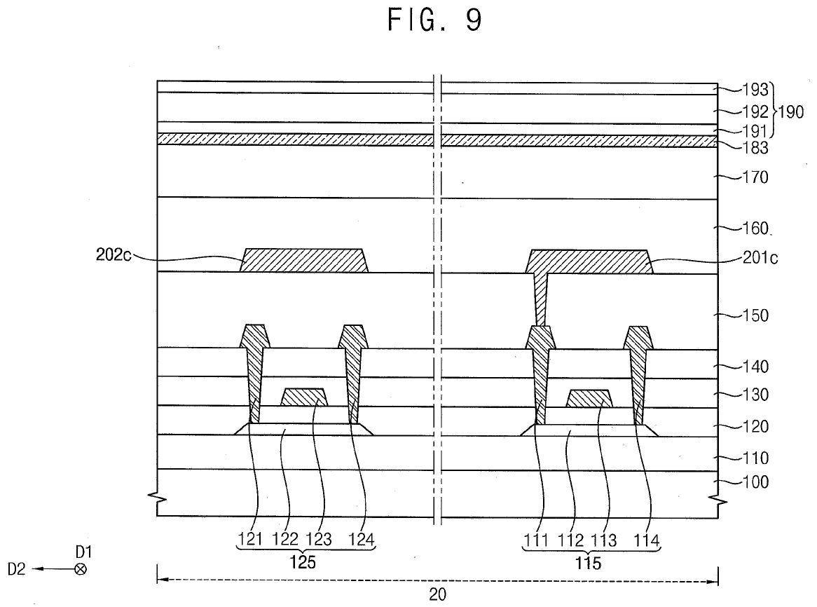

Referring to FIG. 9, the first signal wiring 201c may overlap the first source pattern 111, the first gate pattern 113, and the first drain pattern 114, and the second signal wiring 202c may overlap the second source pattern 121, the second gate pattern 123, and the second drain pattern 124.

However, this is exemplary, and the second signal wiring 202c may overlap the first source pattern 111, the first gate pattern 113, and the first drain pattern 114, and the first signal wiring 201c may overlap the second drain pattern 124.

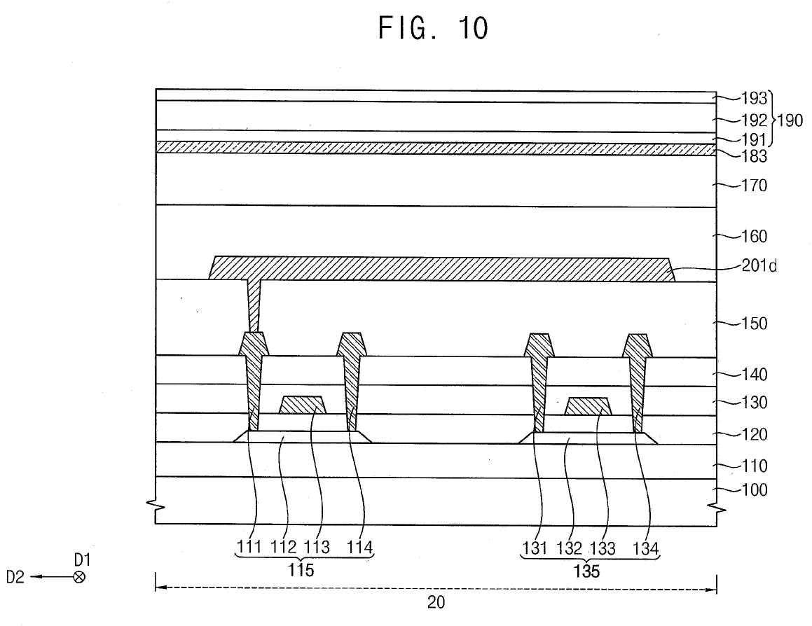

FIG. 10 is a schematic cross-sectional view illustrating an embodiment in which a gate driving part of the display apparatus of FIG. 1 is cut.

Referring to FIG. 10, the display apparatus 1000 may include a third driving part transistor 135. The third driving part transistor 135 may include a third source pattern 131, a third drain pattern 134, a third gate pattern 133, and a third active pattern 132. The first signal wiring 201d may be electrically connected to the first source pattern 111 of the first driving part transistor 115. The first signal wiring 201d may overlap the first driving part transistor 115 and the third driving part transistor 135. However, this is exemplary, and the first signal wiring 201d may overlap the entire first driving part transistor 115 and may overlap a part of the third driving part transistor 135. For example, in an embodiment, the first signal wiring 201d may overlap separate driving part transistors.

As described above, a dead space of the display apparatus 1000 may be reduced as the first signal wiring 201d, which was conventionally disposed in the second direction D2 of the plurality of driving part transistors, is disposed to overlap the plurality of transistors. Also, the overall length of the signal wiring may be reduced, so that the resistance may decrease.

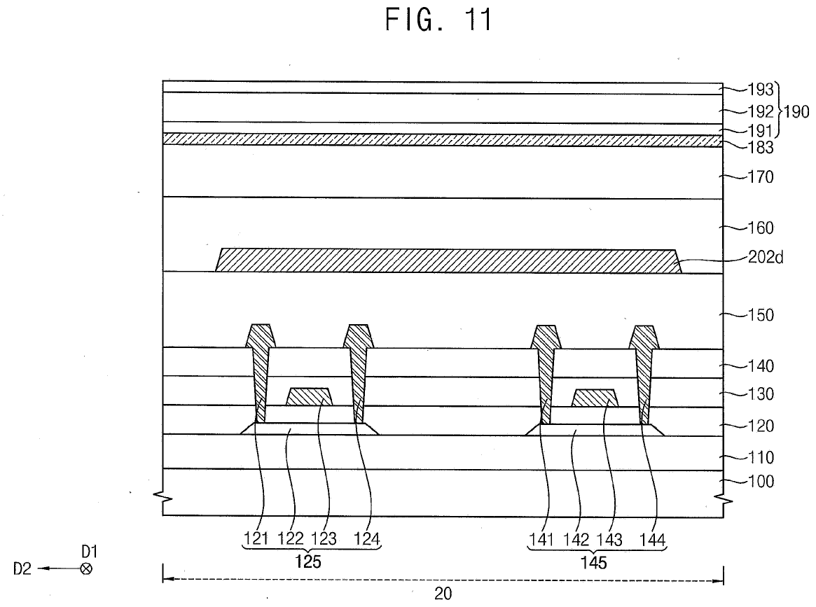

FIG. 11 is a schematic cross-sectional view illustrating an embodiment in which a gate driving part of the display apparatus of FIG. 1 is cut.

Referring to FIG. 11, the display device 1000 may include a fourth driving part transistor 145. The fourth driving part transistor 145 may include a fourth source pattern 141, a fourth drain pattern 144, a fourth gate pattern 143, and a fourth active pattern 142. The second signal wiring 202d may overlap the second driving part transistor 125 and the fourth driving part transistor 145. However, this is exemplary, and the second signal wiring 202d may overlap the entire second driving part transistor 125 and may overlap a part of the fourth driving part transistor 145. As an example, in an embodiment, the second signal wiring 202d may overlap separate driving part transistors.

As described above, a dead space of the display apparatus 1000 may be reduced as the first signal wiring 202d, which was conventionally disposed in the second direction D2 of the plurality of driving part transistors, is disposed to overlap the plurality of transistors. Also, the overall length of the signal wiring may be reduced, so that the resistance may decrease.

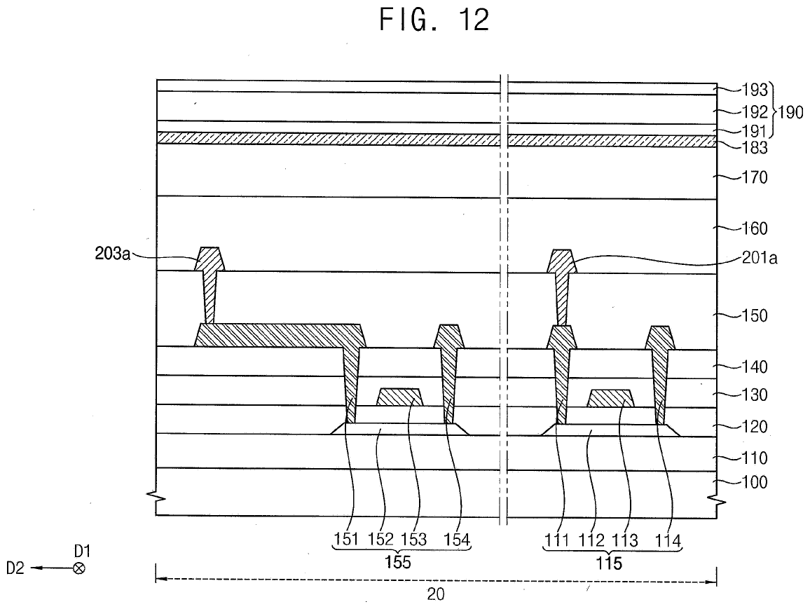

FIG. 12 is a schematic cross-sectional view illustrating an embodiment in which a gate driving part of the display apparatus of FIG. 1 is cut.

Referring to FIG. 12, the display apparatus 1000 may include a clock signal wiring 203a and a fifth driving part transistor 155. The fifth driving part transistor 155 may include a fifth source pattern 151, a fifth drain pattern 154, a fifth gate pattern 153, and a fifth active pattern 152. The clock signal wiring 203a may be electrically connected to the fifth source pattern 151 of the fifth driving part transistor 155. In an embodiment, the clock signal wiring 203a may provide a clock signal to the fifth driving part transistor 155. The clock signal may be applied to the clock signal wiring 203a. In an embodiment, the clock signal wiring 203a may be disposed on the same layer as the first signal wiring 201a. The clock signal wiring 203a may not overlap the driving part transistors. For example, the fifth driving part transistor 155 may correspond to the sixth transistor M6 of FIG. 4.

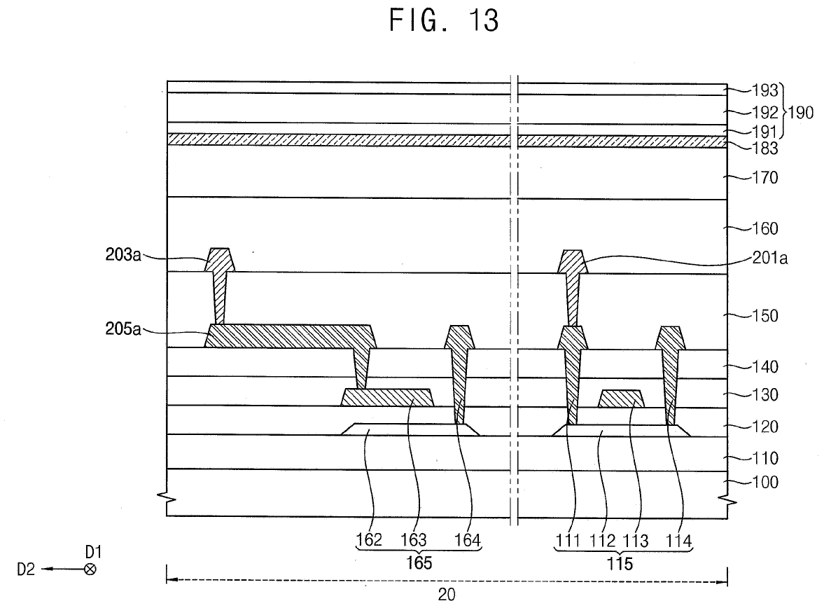

FIG. 13 is a schematic cross-sectional view illustrating an embodiment in which a gate driving part of the display apparatus of FIG. 1 is cut.

Referring to FIG. 13, the display apparatus 1000 may include a clock signal wiring 203a and a sixth driving part transistor 165. The sixth driving part transistor 165 may include a sixth source pattern (not illustrated), a sixth drain pattern 164, a sixth gate pattern 163, and a sixth active pattern 162. The clock signal wiring 203a may transmit a clock signal to the sixth gate pattern 163 through a bridge electrode 205a. In an embodiment, the bridge electrode 205a may be disposed on the same layer as the sixth drain pattern 164. For example, the sixth driving part transistor 165 may correspond to the third transistor M3 of FIG. 4.

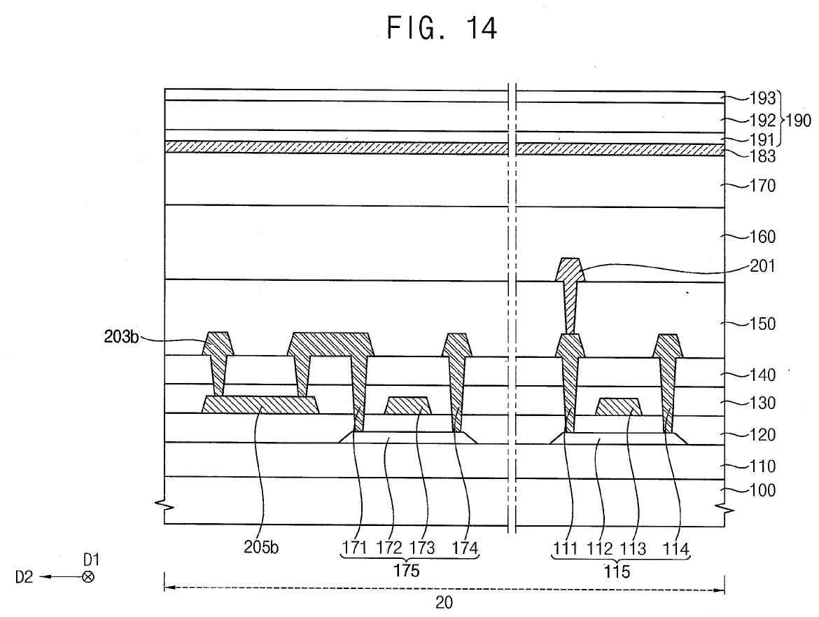

FIG. 14 is a schematic cross-sectional view illustrating an embodiment in which a gate driving part of the display apparatus of FIG. 1 is cut.

Referring to FIG. 14, the display apparatus 1000 may include a clock signal wiring 203b, a bridge electrode 205b, and a seventh driving part transistor 175. The seventh driving part transistor may include a seventh source pattern 171, a seventh drain pattern 174, a seventh active pattern 172, and a seventh gate pattern 173. In an embodiment, the clock signal wiring 203b may transmit a clock signal to the seventh source pattern 171 through the bridge electrode 205b. The clock signal wiring 203b may be disposed on the same layer as the seventh source pattern 171 and may not overlap the driving part transistors. In an embodiment, the bridge electrode 205b may be disposed on the same layer as the seventh gate pattern 173. For example, the seventh driving part transistor 175 may correspond to the sixth transistor M6 of FIG. 4.

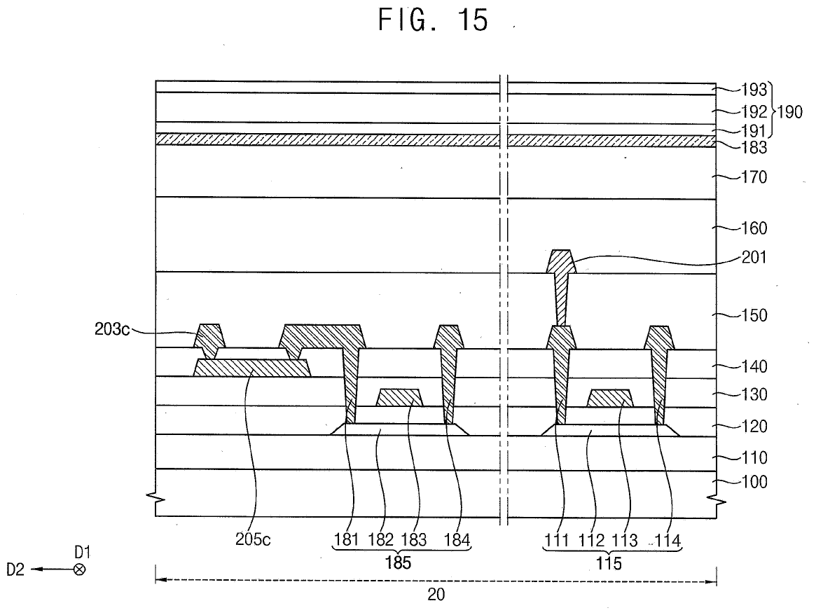

FIG. 15 is a schematic cross-sectional view illustrating an embodiment in which a gate driving part of the display apparatus of FIG. 1 is cut.

Referring to FIG. 15, the display apparatus 1000 may include a clock signal wiring 203c, a bridge electrode 205c, and an eighth driving part transistor 185. The eighth driving part transistor may include an eighth source pattern 181, an eighth drain pattern 184, an eighth active pattern 182, and an eighth gate pattern 183. In an embodiment, the clock signal wiring 203c may transmit a clock signal to the eighth source pattern 181 through the bridge electrode 205c. The clock signal wiring 203c may be disposed on the same layer as the eighth source pattern 181 and may not overlap the driving part transistors. In an embodiment, the bridge electrode 205c may be disposed on the eighth gate pattern 173. For example, the eighth driving part transistor 185 may correspond to the sixth transistor M6 of FIG. 4.

The disclosure may be applied to a display apparatus. For example, the disclosure may be applied to a smart phone, a cellular phone, a video phone, a smart pad, a smart watch, a tablet PC, a vehicle navigation system, a television, a computer monitor, a laptop, a head mounted display apparatus, MP3 player, and the like within the spirit and the scope of the disclosure.

The foregoing is illustrative of example embodiments and is not to be construed as limiting thereof. Although example embodiments have been described, those skilled in the art will readily appreciate that many modifications are possible in example embodiments without materially departing from the novel teachings and advantages of the disclosure. Accordingly, all such modifications are intended to be included within the scope of the disclosure as defined in the claims. Therefore, it is to be understood that the foregoing is illustrative of example embodiments and is not to be construed as limited to the example embodiments disclosed, and that modifications to the disclosed example embodiments, as well as other example embodiments, are intended to be included within the scope of the appended claims.

What is claimed is:

1. A display apparatus comprising:
a display;
a driver including a plurality of shift registers arranged along a first direction, the driver providing a driving signal to the display; and
a first signal wiring disposed on the driver, extending along the first direction, and transmitting a first driving signal to the plurality of shift resisters, wherein
each of the plurality of shift registers includes at least one driver transistor, and
the first signal wiring is electrically connected to a source electrode of a first driver transistor and overlaps the first driver transistor.

2. The display apparatus of claim 1, wherein the first signal wiring transmits the first driving signal of a constant voltage.

3. The display apparatus of claim 1, wherein the first signal wiring overlaps the source electrode of the first driver transistor.

4. The display apparatus of claim 1, wherein the first signal wiring overlaps the source electrode and a gate electrode of the first driver transistor.

5. The display apparatus of claim 1, wherein the first signal wiring overlaps the source electrode, a drain electrode, and a gate electrode of the first driver transistor.

6. The display apparatus of claim 1, wherein the first signal wiring overlaps two or more driver transistors.

7. The display apparatus of claim 1, further comprising:
a second driver transistor; and
a second signal wiring extending along the first direction and transmitting a second driving signal to a first shift register of the plurality of shift registers,
wherein the second signal wiring overlaps the second driver transistor.

8. The display apparatus of claim 7, wherein the second signal wiring transmits the second driving signal as a start signal.

9. The display apparatus of claim 7, wherein the first signal wiring and the second signal wiring are disposed on a same layer.

10. The display apparatus of claim 7, wherein the first signal wiring and the second signal wiring are spaced apart from each other in a second direction perpendicular to the first direction.

11. The display apparatus of claim 7, wherein the second signal wiring overlaps a source electrode, a drain electrode, or a gate electrode of the second driver transistor

12. The display apparatus of claim 7, wherein the second signal wiring overlaps a source electrode and a gate electrode of the second driver transistor.

13. The display apparatus of claim 7, wherein the second signal wiring overlaps a drain electrode and a gate electrode of the second driver transistor.

14. The display apparatus of claim 7, wherein the second signal wiring overlaps a source electrode, a drain electrode, and a gate electrode of the second driver transistor.

15. The display apparatus of claim 7, wherein the second signal wiring overlaps two or more driver transistors.

16. The display apparatus of claim 1, further comprising:
a clock signal wiring providing a clock signal to a second driver transistor and extending along the first direction.

17. The display apparatus of claim 16, wherein
the clock signal wiring and the first signal wiring are disposed on a same layer, and
the clock signal wiring does not overlap the first driver transistor and the second driver transistor.

18. The display apparatus of claim 17, wherein the clock signal wiring is electrically connected to a source electrode of the second driver transistor.

19. The display apparatus of claim 16, wherein
the clock signal wiring and a source electrode of the first driver transistor are disposed on a same layer, and
the clock signal wiring does not overlap the first driver transistor and the second driver transistor.

20. The display apparatus of claim 19, wherein the clock signal wiring is electrically connected to the second driver transistor by a bridge electrode.

21. The display apparatus of claim 20, wherein the bridge electrode and a gate electrode of the first driver transistor are disposed on a same layer.

22. The display apparatus of claim 1, the display comprising:
a light emitting element;
a pixel driving transistor including a gate electrode, a source electrode, and a drain electrode; and
a connection electrode electrically connecting the light emitting element and the drain electrode of the pixel driving transistor,
wherein the first signal wiring and the connection electrode are disposed on a same layer.
